(19) United States
(12) Patent Application Publication
(10) Pub. No.: US 2020/0150365 A1
(43) Pub. Date: May 14, 2020

(54) OPTICAL MODULE

(71) Applicant: FUJITSU LIMITED, Kawasaki-shi (JP)

(72) Inventors: Tetsuro Yamada, Kawasaki (JP); Yasushi Masuda, Kawasaki (JP); NAOKI ISHIKAWA, Nagano (JP); Shuichi Takeuchi, Chikuma (JP)

(73) Assignee: FUJITSU LIMITED, Kawasaki-shi (JP)

(21) Appl. No.: 16/677,737

(22) Filed: Nov. 8, 2019

(30) Foreign Application Priority Data
Nov. 12, 2018 (JP) 2018-212122

(51) Int. Cl. G02B 6/42; H01L 25/16; H01L 23/538; H01L 23/367; H01L 31/024; H01L 31/02; H01L 31/0203

(52) U.S. Cl. CPC G02B 6/4269; G02B 6/4274; H01L 25/167; H01L 23/5386; H01L 23/3675; H01L 24/16; H01L 31/02016; H01L 31/02002; H01L 25/165; H01L 31/0203; H01L 31/024

(57) ABSTRACT

An optical module includes: a substrate in which a conductor is disposed in an inner layer and a part of the conductor is exposed at an end surface; and an optical element bonded to the part of the conductor exposed at the end surface of the substrate.

### CROSS-REFERENCE TO RELATED APPLICATION

This application is based upon and claims the benefit of priority of the prior Japanese Patent Application No. 2018-212122, filed on Nov. 12, 2018, the entire contents of which are incorporated herein by reference.

### FIELD

The embodiments discussed herein are related to an optical module.

### BACKGROUND

There is an optical module in which a mirror which performs optical path conversion is provided between an optical element mounted over a substrate and an optical fiber. However, in a case where the mirror is provided between the optical element and the optical fiber, it is difficult to accurately position the optical element and the optical fiber. As a result, accuracy of optical coupling deteriorates and a coupling loss increases, in some cases.

International Publication Pamphlet No. WO 2007/088959 is an example of related art.

### SUMMARY

According to an aspect of the embodiments, an optical module includes: a substrate in which a conductor is disposed in an inner layer and a part of the conductor is exposed at an end surface; and an optical element bonded to the part of the conductor exposed at the end surface of the substrate.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a perspective view illustrating a configuration of an optical module according to a first embodiment;

FIG. 2 is a cross-sectional view taken along a line II-II in FIG. 1;

FIG. 3 is a perspective view of a substrate according to the first embodiment when viewed from an end surface side;

FIG. 4 is a cross-sectional view schematically illustrating a configuration of an optical module according to a second embodiment; and

FIG. 5 is a cross-sectional view schematically illustrating a configuration of an optical module according to a third embodiment.

### DESCRIPTION OF EMBODIMENTS

For example, an optical module which performs optical coupling between an optical element and an optical fiber without a mirror has been studied. For example, it is proposed to flip-chip mount an optical element on an end surface of a substrate opposite to a tip of an optical fiber.

For example, in an optical module, an amount of heat generated by an optical element tends to increase as a speed of optical transmission increases. When the amount of heat generated by the optical element increases, a performance of the optical element may deteriorate. In a case in which the optical element is flip-chip mounted on the end surface of the substrate, since the optical element and the end surface of the substrate are bonded to each other via a bump, a contact area between the optical element and the end surface of the substrate is not secured. Accordingly, heat emitted from the optical element is not efficiently absorbed to the end surface side of the substrate. As a result, there is a possibility that heat dissipation efficiency in the optical module may be impaired.

An optical module capable of improving heat dissipation efficiency may be provided.

Hereinafter, embodiments of an optical module disclosed in the present application will be described in detail with reference to the accompanying drawings. It is to be understood that the disclosed technology is not limited to these embodiments. In the embodiments, the same reference numerals denote components having substantially the same functions and an overlapped description thereof is omitted.

### First Embodiment

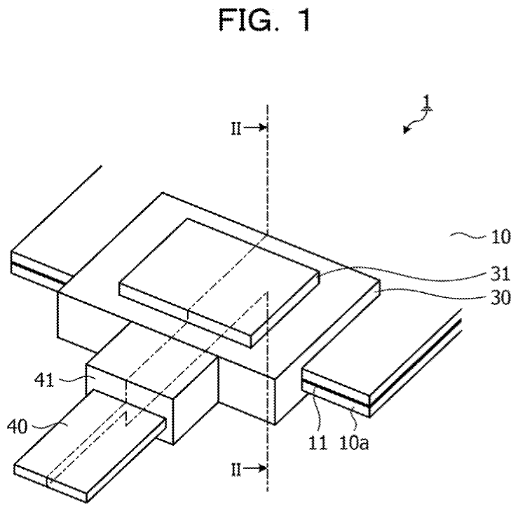

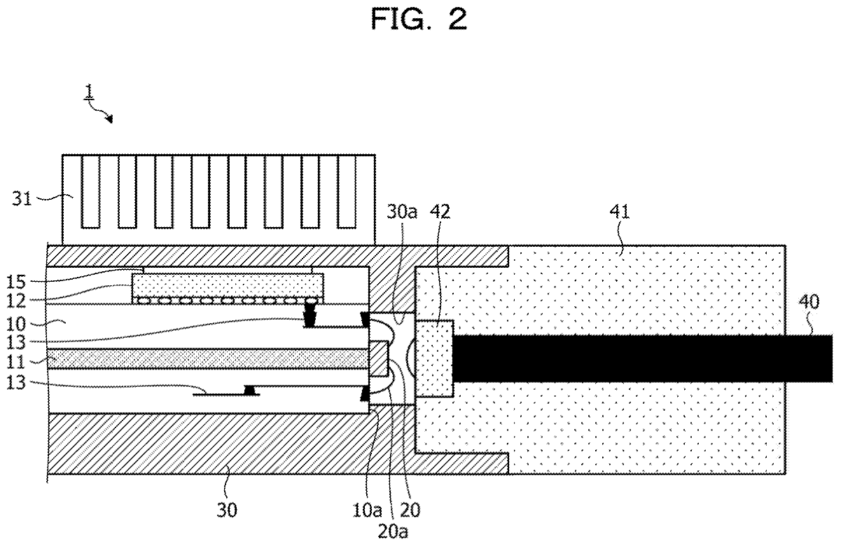

FIG. 1 is a perspective view illustrating a configuration of an optical module 1 according to a first embodiment. FIG. 2 is a cross-sectional view taken along a line II-II in FIG. 1. The optical module 1 illustrated in FIG. 1 and FIG. 2 includes a substrate 10, an optical element 20, a cover member 30, and an optical fiber 40.

The substrate 10 is, for example, a printed wiring substrate such as a glass epoxy substrate. Various components constituting the optical module 1 are mounted over the substrate 10. A conductor 11 which functions as a ground electrode is disposed in an inner layer of the substrate 10. The conductor 11 is made of, for example, a metal such as copper having high thermal conductivity. The conductor 11 is coupled to each ground electrode disposed over a surface layer of the substrate 10. A part of the conductor 11 is exposed at an end surface 10a of the substrate 10. A driving circuit 12 of the optical element 20 is mounted over the surface layer of the substrate 10. A wiring 13 coupled to the driving circuit 12 is disposed in the inner layer of the substrate 10. A part of the wiring 13 is exposed at the end surface 10a of the substrate 10. A pad for wire bonding may be formed at the part of the wiring 13 exposed at the end surface 10a of the substrate 10.

The optical element 20 is, for example, a photoelectric conversion element for performing mutual conversion between an electric signal and an optical signal, and is bonded to the part of the conductor 11 exposed at the end surface 10a of the substrate 10. For example, the optical element 20 is soldered to the part of the conductor 11 exposed at the end surface 10a of the substrate 10. In this way, the optical element 20 is bonded to the part of the conductor 11 exposed at the end surface 10a of the substrate 10 in a surface contact state.

In the optical module 1, an amount of heat generated by the optical element 20 tends to increase as a speed of optical transmission increases. When the amount of heat generated by the optical element 20 increases, a performance of the optical element 20 may deteriorate.

Therefore, in the optical module 1, as illustrated in FIG. 2, the optical element 20 is bonded to the part of the conductor 11 exposed at the end surface 10a of the substrate 10. In this way, since the optical element 20 and the part of the conductor 11 exposed at the end surface 10a of the substrate 10 are bonded in a surface contact state, a contact area between the optical element 20 and the part of the conductor 11 may be secured. Accordingly, heat emitted from the optical element 20 is efficiently absorbed by the conductor 11. As a result, it is possible to improve heat dissipation efficiency in the optical module 1.

The optical element 20 is electrically coupled to the part of the wiring 13 exposed at the end surface 10a of the substrate 10. For example, the optical element 20 is coupled to the part of the wiring 13 exposed at the end surface 10a of the substrate 10 via a bonding wire 20a. Thus, an electric signal output from the driving circuit 12 is input to the optical element 20 via the wiring 13 and the bonding wire 20a, is converted into an optical signal by the optical element 20, and is output to the optical fiber 40. Since the wiring 13 which transmits the electric signal is disposed in the inner layer of the substrate 10, it is possible to reduce reflection and radiation of the electric signal in the wiring 13.

The cover member 30 is formed of a metal material such as aluminum, and is attached to the substrate 10 so as to cover the end surface 10a of the substrate 10, the surface layer, over which the driving circuit 12 is disposed, of the substrate 10, and a back layer of the substrate 10. The cover member 30 is provided with an opening 30a which optically couples the optical element 20 and the optical fiber 40. A manner in which the cover member 30 is attached to the substrate 10 will be described in detail below.

The optical fiber 40 is fixed to the cover member 30 in a state in which a tip thereof is housed in a translucent ferrule 41. A lens 42 which condenses light is provided at an end surface of the tip of the optical fiber 40. The optical fiber 40 transmits an optical signal to another optical transmission apparatus, for example. For example, the optical fiber 40 transmits an optical signal output from the optical element 20 to another optical transmission apparatus or the like. The optical fiber 40 transmits an optical signal transmitted from another optical transmission apparatus so as to input the optical signal to the optical element 20, for example.

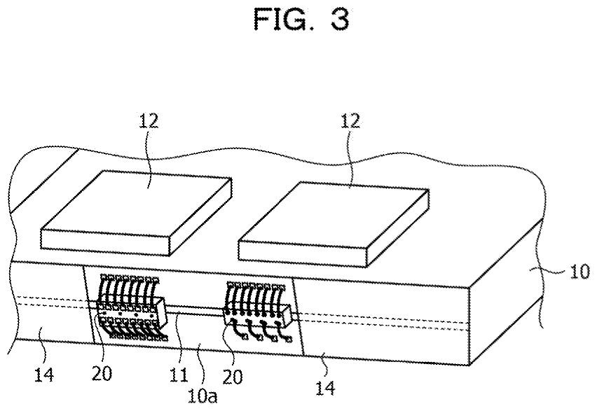

Hereinafter, with reference to FIG. 2 and FIG. 3, a manner of attaching the cover member 30 to the substrate 10 will be described specifically. FIG. 3 is a perspective view of the substrate 10 according to the first embodiment when viewed from the end surface 10a side. In FIG. 3, the illustration of the cover member 30 is omitted for convenience of explanation.

As illustrated in FIG. 2 and FIG. 3, the optical element 20 is bonded to the part of the conductor 11 exposed at the end surface 10a of the substrate 10. The driving circuit 12 for the optical element 20 is mounted over the surface layer of the substrate 10. In the example illustrated in FIG. 3, the two optical elements 20 are bonded to the part of the conductor 11, and the two driving circuits 12 respectively corresponding to the two optical elements 20 are mounted over the surface layer of the substrate 10.

As illustrated in FIG. 3, the substrate 10 includes a plating film 14 coupled to the part of the conductor 11 exposed at the end surface 10a in a region which does not overlap with the optical element 20 in the end surface 10a. The cover member 30 is attached to the substrate 10 to be in contact with the plating film 14. In the example illustrated in FIG. 3, the plating film 14 is formed in regions that sandwich the two optical elements 20 therebetween along a width direction of the substrate 10, in the end surface 10a of the substrate 10. The cover member 30 is in contact with the plating film 14 formed in the region in which the two optical elements 20 are sandwiched in the end surface 10a of the substrate 10. In this way, a contact area between the part of the conductor 11 exposed at the end surface 10a of the substrate 10 and the cover member 30 is expanded by a surface area of the plating film 14. Accordingly, heat emitted from the optical element 20 and absorbed by the conductor 11 is transmitted to the cover member 30 by the plating film 14, and is efficiently released into air by the cover member 30. As a result, in the optical module 1, it is possible to improve heat dissipation efficiency of a path reaching the cover member 30 from the optical element 20 via the conductor 11.

As illustrated in FIG. 2, the cover member 30 is attached to the substrate 10 so as to cover the surface layer, over which the driving circuit 12 is disposed, of the substrate 10. For example, the cover member 30 is in contact with the driving circuit 12 via a thermal conductive member 15 such as a thermal conductive sheet or a thermal conductive bonding member. Thus, heat emitted from the driving circuit 12 is transmitted to the cover member 30 by the thermal conductive member 15, and is efficiently released into air by the cover member 30. As a result, in the optical module 1, it is possible to improve heat dissipation efficiency of a path reaching the cover member 30 from the driving circuit 12 via the thermal conductive member 15.

The cover member 30 includes a heat sink 31 over a surface opposite to a surface that is in contact with the driving circuit 12. Thus, heat transmitted from the driving circuit 12 to the cover member 30 by the thermal conductive member 15 is efficiently released into air by the heat sink 31. As a result, in the optical module 1, it is possible to further improve heat dissipation efficiency of the path reaching the cover member 30 from the driving circuit 12 via the thermal conductive member 15.

As described above, the optical module 1 according to the present embodiment includes the substrate 10 and the optical element 20. In the substrate 10, the conductor 11 is disposed in an inner layer, and the part of the conductor 11 is exposed at the end surface 10a. The optical element 20 is bonded to the part of the conductor 11 exposed at the end surface 10a of the substrate 10. With the configuration of the optical module 1, it is possible to improve heat dissipation efficiency in the optical module 1.

### Second Embodiment

An optical module 1A according to a second embodiment has substantially the same structure as the optical module 1 according to the first embodiment except that a plurality of conductors 11 are disposed in the inner layer of the substrate 10 and the optical element 20 is bonded to a part of each of the conductors 11 exposed at the end surface 10a. Therefore, in the second embodiment, the same reference numerals are used to designate the same components as those in the first embodiment described above, and a detailed description thereof will be omitted.

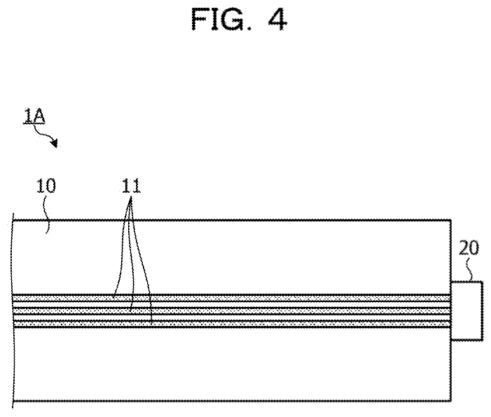

FIG. 4 is a cross-sectional view schematically illustrating a configuration of the optical module 1A according to the second embodiment. FIG. 4 corresponds to the cross-sectional view taken along the line II-II in FIG. 1. In FIG. 4, for convenience of explanation, the illustrations of the cover member 30, the optical fiber 40, and so on are omitted. In the inner layer of the substrate 10 of the optical module 1A illustrated in FIG. 4, the plurality of conductors 11 which function as ground electrodes are disposed along a thickness direction of the substrate 10. A part of each of the conductors 11 is exposed at the end surface 10a of the substrate 10.

The optical element 20 is bonded to the part of each of the conductors 11 exposed at the end surface 10a of the substrate 10. For example, the optical element 20 is soldered to the part of each of the conductors 11 exposed at the end surface 10a of the substrate 10. In this way, the optical element 20 is bonded to the part of each of the conductors 11 exposed at the end surface 10a of the substrate 10 in a surface contact state.

As described above, in the optical module 1A according to the present embodiment, the plurality of conductors 11 are disposed in the inner layer of the substrate 10 along the thickness direction of the substrate 10, and the parts of the conductors 11 are exposed at the end surface 10a. The optical element 20 is bonded to the part of each of the conductors 11 exposed at the end surface 10a of the substrate 10. With the configuration of the optical module 1A, heat emitted from the optical element 20 is efficiently absorbed by the plurality of conductors 11. As a result, even in a case where it is difficult to dispose the single conductor 11 having a large thickness in the inner layer of the substrate 10 due to space restrictions, heat dissipation efficiency in the optical module 1A may be improved.

### Third Embodiment

An optical module 1B according to a third embodiment has substantially the same configuration as the optical module 1A according to the second embodiment except that a thermal conductive member is provided between the plurality of conductors 11. Therefore, in the third embodiment, the same reference numerals are used to designate the same components as those in the second embodiment described above, and a detailed description thereof will be omitted.

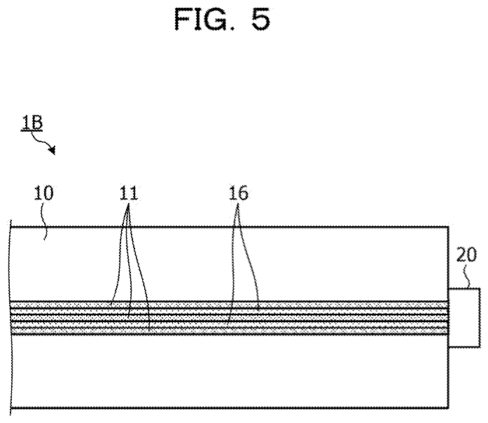

FIG. 5 is a cross-sectional view schematically illustrating a configuration of the optical module 1B according to the third embodiment. FIG. 5 corresponds to the cross-sectional view taken along the line II-II in FIG. 1. In FIG. 5, for convenience of explanation, the illustrations of the cover member 30, the optical fiber 40, and so on are omitted. In the optical module 1B illustrated in FIG. 5, the substrate 10 includes thermal conductive members 16 of a thermal conductive resin or the like, for example, between the plurality of conductors 11.

As described above, in the optical module 1B according to the present embodiment, the substrate 10 includes the thermal conductive members 16 of a thermal conductive resin or the like, for example, between the plurality of conductors 11. With the configuration of the optical module 1B, heat to be emitted from the optical element 20 and absorbed by the plurality of conductors 11 is uniformly distributed to the plurality of conductors 11 by the thermal conductive members 16. As a result, it is possible to further improve heat dissipation efficiency in the optical module 1B.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An optical module comprising:
a substrate in which a conductor is disposed in an inner layer and a part of the conductor is exposed at an end surface; and
an optical element bonded to the part of the conductor exposed at the end surface of the substrate.

2. The optical module according to claim 1,
wherein the conductor includes a plurality of conductors,
wherein in the substrate, the plurality of conductors are disposed in the inner layer along a thickness direction of the substrate, and the part of each of the plurality of conductors is exposed at the end surface, and
wherein the optical element is bonded to the part of each of the plurality of conductors exposed at the end surface of the substrate.

3. The optical module according to claim 2, wherein the substrate includes a thermal conductive member between the plurality of conductors.

4. The optical module according to claim 1, further comprising:
a cover member configured to cover at least the end surface of the substrate,
wherein the substrate includes a plating film coupled to the exposed part of the conductor in a region which does not overlap with the optical element in the end surface, and
wherein the cover member is in contact with the plating film.

5. The optical module according to claim 4,
wherein in the substrate, a driving circuit for the optical element is mounted over a surface layer, a wiring coupled to the driving circuit is disposed in the inner layer, and a part of the wiring is exposed at the end surface,
wherein the optical element is electrically coupled to the part of the wiring exposed at the end surface of the substrate, and
wherein the cover member further covers the surface layer, over which the driving circuit is disposed, of the substrate, and is in contact with the driving circuit via a thermal conductive member.

6. The optical module according to claim 5, wherein the cover member includes a heat sink over a surface opposite to a surface that is in contact with the driving circuit.
